(19) United States
(12) Patent Application Publication
(10) Pub. No.: US 2021/0391529 A1
(43) Pub. Date: Dec. 16, 2021

(54) MANUFACTURING METHOD OF DIELECTRIC ELASTOMER TRANSDUCER, AND DIELECTRIC ELASTOMER TRANSDUCER

(71) Applicants: Seiki CHIBA, Meguro-ku, Tokyo (JP); Mikio WAKI, Sakura-shi, Tochigi (JP); ZEON CORPORATION, Chiyoda-ku, Tokyo (JP)

(72) Inventors: Seiki CHIBA, Meguro-ku, Tokyo (JP); Mikio WAKI, Sakura-shi, Tochigi (JP); Mitsugu UEJIMA, Chiyoda-ku, Tokyo (JP); Makoto TAKESHITA, Chiyoda-ku, Tokyo (JP)

(73) Assignees: Seiki CHIBA, Meguro-ku, Tokyo (JP); Mikio WAKI, Sakura-shi, Tochigi (JP); ZEON CORPORATION, Chiyoda-ku, Tokyo (JP)

(21) Appl. No.: 17/287,667

(22) PCT Filed: Oct. 23, 2019
(86) PCT No.: PCT/JP2019/041431

§ 371 Date: Apr. 22, 2021

(30) Foreign Application Priority Data
Oct. 31, 2018 (JP) 2018-204561

(51) Int. Cl. H01L 41/317; H01L 41/04; H01L 41/047; H01L 41/053; H01L 41/193; H01L 41/29; H01L 41/45

(52) U.S. Cl. CPC H01L 41/317; H01L 41/042; H01L 41/047; H01L 41/45; H01L 41/193; H01L 41/29; H01L 41/0536

(57) ABSTRACT

A method for forming a dielectric elastomer transducer of the present invention includes: a first electrode layer fixing step of fixing a first electrode layer to a target object; a dielectric elastomer layer fixing step of fixing a dielectric elastomer layer to the first electrode layer; and a second electrode layer fixing step of fixing a second electrode layer to the dielectric elastomer layer. This configuration ensures that the dielectric elastomer transducer highly conforms to the target object.

### TECHNICAL FIELD

The present invention relates to methods for manufacturing dielectric elastomer transducers and also to dielectric elastomer transducers.

### BACKGROUND ART

Dielectric elastomer transducers that include dielectric elastomer layers are attracting attention as having high energy conversion efficiency. Such a dielectric elastomer transducer converts one form of energy into another by exploiting deformation (expansion and contraction) of a dielectric elastomer layer.

For example, the dielectric elastomer layer can be deformed by external force to generate power, thereby converting mechanical energy into electrical energy. In this case, the dielectric elastomer transducer works as a power generator. In another example, the dielectric elastomer layer can be deformed by a pair of electrodes to produce a driving force when electric charge is applied to the electrodes. In this case, the dielectric elastomer transducer works as an actuator. The dielectric elastomer transducer can be used also as a sensor based on the change in the capacitance of the dielectric elastomer transducer as an electrical condenser (capacitor).

For a dielectric elastomer transducer to work as a power generator or a sensor, the dielectric elastomer transducer may be required to be in intimate contact with an object being an actuation or sensor target. Although dielectric elastomer layers are generally made of relatively compliant materials, a dielectric elastomer transducer also includes a pair of electrodes. It may not be easy to fix the dielectric elastomer transducer to a target object in a manner ensuring that the dielectric elastomer transducer closely conforms to the shape and motion of the target object.

### PRIOR ART DOCUMENT

Patent Document 1: JP-A-2009-124875

### SUMMARY OF THE INVENTION

### Problem to be Solved by the Invention

The present invention has been conceived in view of the circumstances noted above and aims to provide a method for manufacturing a dielectric elastomer transducer that can closely conform to a target object. The present invention also aims to provide such a dielectric elastomer transducer.

### Means to Solve the Problem

A first aspect of the present invention provides a method for manufacturing a dielectric elastomer transducer. The method includes: a first electrode layer fixing step of fixing a first electrode layer to a target object; a dielectric elastomer layer fixing step of fixing a dielectric elastomer layer to the first electrode layer; and a second electrode layer fixing step of fixing a second electrode layer to the dielectric elastomer layer.

In a preferable embodiment of the present invention, the first electrode layer fixing step includes material application to form the first electrode layer fixed to the target object.

In a preferable embodiment of the present invention, the first electrode layer fixing step includes bonding to fix the first electrode layer to the target object.

In a preferable embodiment of the present invention, at least one of the dielectric elastomer layer fixing step or the second electrode layer fixing step includes material application to form the corresponding layer.

In a preferable embodiment of the present invention, at least one of the dielectric elastomer layer fixing step or the second electrode layer fixing step includes bonding to fix the corresponding layer.

A second aspect of the present invention provides a method for manufacturing a dielectric elastomer transducer. The method includes: a dielectric elastomer layer fixing step of fixing a dielectric elastomer layer to a surface of a target object, the surface being composed of an electric conductor and comprising a first electrode layer; and a second electrode layer fixing step of fixing a second electrode layer to the dielectric elastomer layer.

A third aspect of the present invention provides method for manufacturing a dielectric elastomer transducer. The method includes: a first electrode layer fixing step of fixing a first electrode layer to a surface of a dielectric elastomer layer that is inflatable to a spherical shape by increasing internal pressure, the surface being an inner surface of the dielectric elastomer layer; and a second electrode layer fixing step of fixing a second electrode layer to an outer surface of the dielectric elastomer layer.

A fourth aspect of the present invention provides a dielectric elastomer transducer including: a first electrode layer formed by applying a material to a target object; a dielectric elastomer layer fixed to the first electrode layer; and a second electrode layer fixed to the dielectric elastomer layer.

A fifth aspect of the present invention provides a dielectric elastomer transducer including: a first electrode layer composed of an electrically conductive surface of a target object; a dielectric elastomer layer fixed to the first electrode layer; and a second electrode layer fixed to the dielectric elastomer layer.

A sixth aspect of the present invention provides a dielectric elastomer transducer including: a dielectric elastomer layer inflatable to a spherical shape by increasing internal pressure; a first electrode layer fixed to an inner surface of the dielectric elastomer layer; and a second electrode layer fixed to an outer surface of the dielectric elastomer layer.

### Advantages of Invention

The present invention can ensure that the dielectric elastomer transducer closely conforms to a target object.

Other features and advantages of the present invention will be more apparent from detailed description given below with reference to the accompanying drawings.

### BRIEF DESCRIPTION OF THE DRAWINGS

FIG. 1 is a sectional view illustrating a method for manufacturing a dielectric elastomer transducer according to a first embodiment of the present invention.

FIG. 2 is a sectional view illustrating a method for manufacturing a dielectric elastomer transducer according to the first embodiment of the present invention.

FIG. 3 is a sectional view illustrating a method for manufacturing a dielectric elastomer transducer according to the first embodiment of the present invention.

FIG. 4 is a sectional view illustrating a method for manufacturing a dielectric elastomer transducer according to the first embodiment of the present invention.

FIG. 5 is a sectional view illustrating a method for manufacturing a dielectric elastomer transducer according to a variation of the first embodiment of the present invention.

FIG. 6 is a sectional view illustrating a method for manufacturing a dielectric elastomer transducer according to a variation of the first embodiment of the present invention.

FIG. 7 is a sectional view illustrating a method for manufacturing a dielectric elastomer transducer according to a variation of the first embodiment of the present invention.

FIG. 8 is a sectional view illustrating a method for manufacturing a dielectric elastomer transducer according to a second embodiment of the present invention.

FIG. 9 is a sectional view illustrating a method for manufacturing a dielectric elastomer transducer according to the second embodiment of the present invention.

FIG. 10 is a sectional view illustrating a method for manufacturing a dielectric elastomer transducer according to the second embodiment of the present invention.

FIG. 11 is a sectional view illustrating a method for manufacturing a dielectric elastomer transducer according to a third embodiment of the present invention.

FIG. 12 is a sectional view illustrating a method for manufacturing a dielectric elastomer transducer according to a fourth embodiment of the present invention.

### MODE FOR CARRYING OUT THE INVENTION

Preferred embodiments of the present invention will be described with reference to the drawings.

### First Embodiment

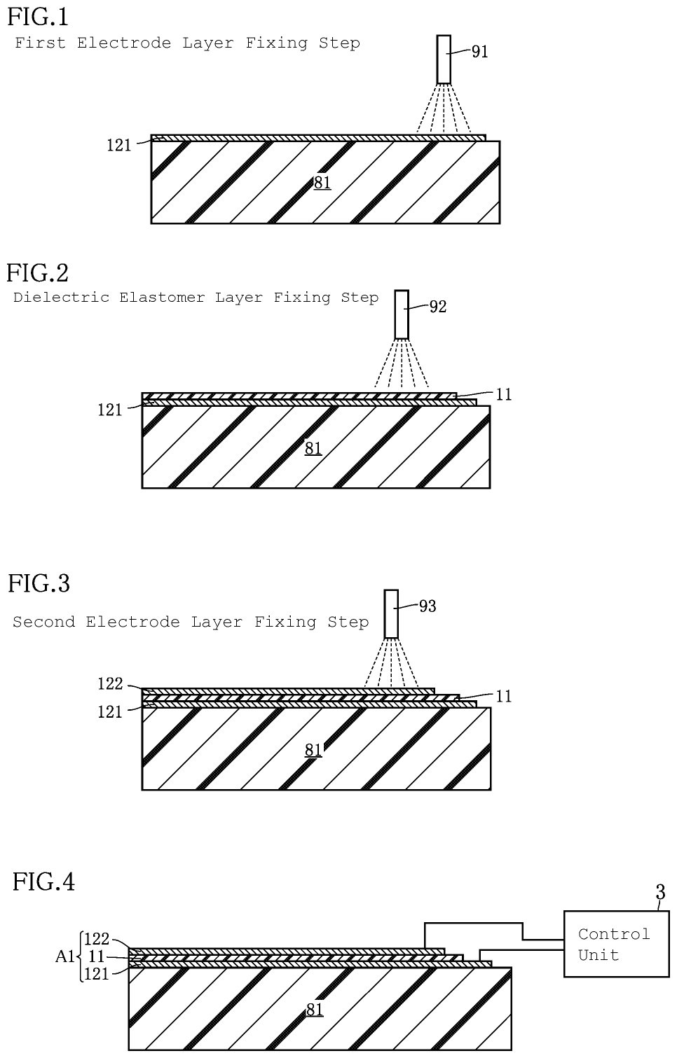

FIGS. 1 to 3 illustrate a method for manufacturing a dielectric elastomer transducer according to a first embodiment of the present invention.

A first electrode layer fixing step is performed as shown in FIG. 1. For the manufacture of a dielectric elastomer transducer used as a power generator, a target object 81 refers to an object that provides a source energy for power generation. For the manufacture of a dielectric elastomer transducer used as a sensor, the target object 81 refers an object whose deformation is to be sensed. In this embodiment, the target object 81 is made of an electrical insulator, which however is merely an example. The material of the target object 81 is not specifically limited.

Specifically, an electrically conductive material is disposed on the target object 81. The conductive material is not specifically limited and can be any of a variety of materials appropriate for forming a first electrode layer 121 that is electrically conductive and compliant to closely follow deformation of a dielectric elastomer layer. For example, the first electrode layer 121 may contain one or more of carbon materials, conductive polymers, and metallic materials. Examples of carbon materials include graphite, fullerene, carbon nanotubes (CNTs) and graphene. The carbon materials may be subjected to one or more of metal doping, metal encapsulation, metal plating and other processing. Examples of conductive polymers include polyacethylene, polythiophene, polypyrrole, polyphenylene, polyphenylene vinylene and polybenzothiazole. Example of metallic materials include silver (Ag), gold (Au) and aluminum (A1), as well as alloys of such metals.

In the illustrated example, fixing the first electrode layer 121 involves application of a material. In particular, a conductive material is applied to the surface of the target object 81 by, for example, spraying the conductive material through an applicator nozzle 91. The conductive material is then solidified or otherwise appropriately processed to form the first electrode layer 121 fixed to the target object 81.

The conductive material may be applied as a mixture with a binder, for example. The binder may be a styrene-isoprene-styrene block polymer dissolved in toluene.

Subsequently, a dielectric elastomer layer fixing step is performed as shown in FIG. 2. That is, a dielectric elastomer layer 11 is fixed to the first electrode layer 121. The dielectric elastomer layer 11 contains one or more elastomers (polymers having rubber-like elasticity). Examples of elastomers include, but not limited to, thermoset elastomers and thermoplastic elastomers.

Thermoset elastomers include, but not limited to, natural rubber, synthetic rubber, silicone rubber, urethane rubber and fluoroelastomers.

Thermoplastic elastomers include, but not limited to, a copolymer of an aromatic vinyl monomer and a conjugated diene monomer. Specific examples of copolymers of an aromatic vinyl monomer and a conjugated diene monomer include: diblock polymers, such as styrene-butadiene block copolymers and styrene-isoprene block polymers; triblock polymers, such as styrene-butadiene-styrene block polymers, styrene-isoprene-styrene (SIS) block polymers, styrene-butadiene-isoprene block polymers, and styrene-isobutylene-styrene (SIBS) block polymers; styrene-containing multiblock polymers, such as styrene-butadiene-styrene-butadiene block polymers, styrene-isoprene-styrene-isoprene block polymers, styrene-butadiene-isoprene-styrene block polymers, styrene-butadiene-styrene-isoprene block polymers and styrene-isobutylene-butadiene-styrene block polymers; and their hydrogenated or partially-hydrogenated additives. Among these examples, block polymers such as SIS are particularly preferable.

In addition to the elastomers listed above, the dielectric elastomer layer 11 may contain one or more other materials, such as various types of additives.

In the illustrated example, fixing the dielectric elastomer layer 11 involves application of a material. In particular, an elastomer material is applied to the surface of the first electrode layer 121 by, for example, spraying the elastomer material from an applicator nozzle 92. The elastomer material is then solidified or otherwise appropriately processed to form the dielectric elastomer layer 11 fixed to the first electrode layer 121.

Subsequently, a second electrode layer fixing step is performed as shown in FIG. 3. In this step, a second electrode layer 122 is fixed to the dielectric elastomer layer 11. In this embodiment, fixing the second electrode layer 122 involves application of a material in a similar manner to the step of fixing the first electrode layer 121. In particular, a conductive material is applied to the surface of the dielectric elastomer layer 11 by, for example, spraying the conductive material through an applicator nozzle 93. The conductive material is then solidified or otherwise appropriately processed to form the second electrode layer 122 fixed to the dielectric elastomer layer 11.

Through the above-described steps, a dielectric elastomer transducer A1 is fabricated as shown in FIG. 4. The dielectric elastomer transducer A1 includes the first electrode layer 121, the dielectric elastomer layer 11 and the second electrode layer 122. The first electrode layer 121, the dielectric elastomer layer 11 and the second electrode layer 122 are formed by applying appropriate materials. In the illustrated example, the dielectric elastomer transducer A1 is connected to a control unit 3.

The control unit 3 is provided to appropriately control processing by the dielectric elastomer transducer A1. For the dielectric elastomer transducer A1 used as an actuator, the control unit 3 includes a power supply circuit for applying a voltage (potential difference) between the first electrode layer 121 and the second electrode layer 122. For the dielectric elastomer transducer A1 used as a power generator, the control unit 3 includes a power supply circuit for applying an initial voltage (potential difference) and an electrical energy recovery circuit. For the dielectric elastomer transducer A1 used as a sensor, the control unit 3 includes a detection circuit for detecting a change in the capacitance of the dielectric elastomer transducer A1.

The following describes advantages of the method for manufacturing a dielectric elastomer transducer and the dielectric elastomer transducer A1 according to the present embodiment.

According to the present embodiment, the manufacture of the dielectric elastomer transducer A1 begins with fixing the first electrode layer 121 to the target object 81. Thus, the first electrode layer 121 is disposed prior to the dielectric elastomer layer 11 and the second electrode layer 122, which possibly interfere with forming the first electrode layer 121 into a desired shape. This ensures that the resulting first electrode layer 121 closely follows the shape and deformation of the target object 81.

Since the first electrode layer 121 is formed by applying a material, the first electrode layer 121 can be appropriately fixed to the target object 81 of a various shape. In addition, the dielectric elastomer layer 11 and the second electrode layer 122 can also be formed by applying a material. This configuration additionally helps the resulting dielectric elastomer transducer A1 to closely conform to the target object 81.

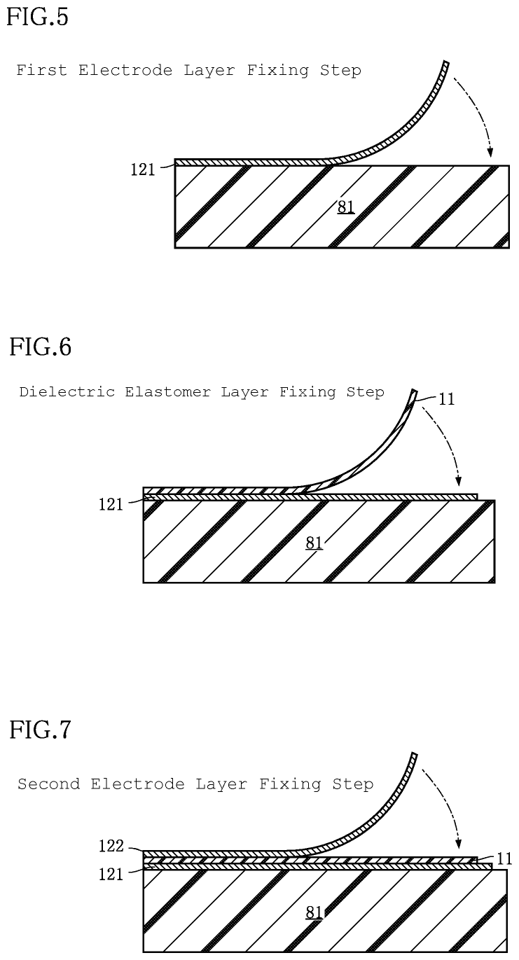

FIGS. 5 to 12 show variations and other embodiments of the present invention. In the figures, the same or similar components to those of the above-described embodiment are denoted by the same reference signs.

### First Variation of First Embodiment

FIG. 5 illustrates a method for manufacturing a dielectric elastomer transducer according to a first variation of the first embodiment of the present invention. In this variation, the first electrode layer fixing step is performed by bonding the first electrode layer 121 to the target object 81.

The method of bonding is not specifically limited. In one preferred example, the bonding is achieved by using a hot-melt adhesive containing an aromatic/conjugated diene copolymer, such as a styrene-isoprene block copolymer or a styrene-butadiene block copolymer.

This variation ensures that the first electrode layer 121 is highly conformable.

### Second Variation of First Embodiment

FIG. 6 illustrates a method for manufacturing a dielectric elastomer transducer according to a second variation of the first embodiment of the present invention. In this variation, the dielectric elastomer layer 11 is fixed by bonding to the first electrode layer 121.

Similarly to the first variation, the method for bonding is not specifically limited. In one preferred example, the bonding is achieved by using a hot-melt adhesive containing an aromatic/conjugated diene copolymer, such as a styrene-isoprene block copolymer or a styrene-butadiene block copolymer.

This variation ensures that the dielectric elastomer layer 11 is highly conformable.

### Third Variation of First Embodiment

FIG. 7 illustrates a method for manufacturing a dielectric elastomer transducer according to a third variation of the first embodiment of the present invention. In this variation, the second electrode layer fixing step is performed by bonding the second electrode layer 122 to the dielectric elastomer layer 11.

Similarly to the first and second variations, the method of bonding is not specifically limited. In one preferred example, the bonding is achieved by using a hot-melt adhesive containing an aromatic/conjugated diene copolymer, such as a styrene-isoprene block copolymer or a styrene-butadiene block copolymer. In another example, the bonding may be achieved by imparting adhesion property to one of the dielectric elastomer layer 11 or the second electrode layer 122.

This variation ensures that the second electrode layer 122 is highly conformable.

### Second Embodiment

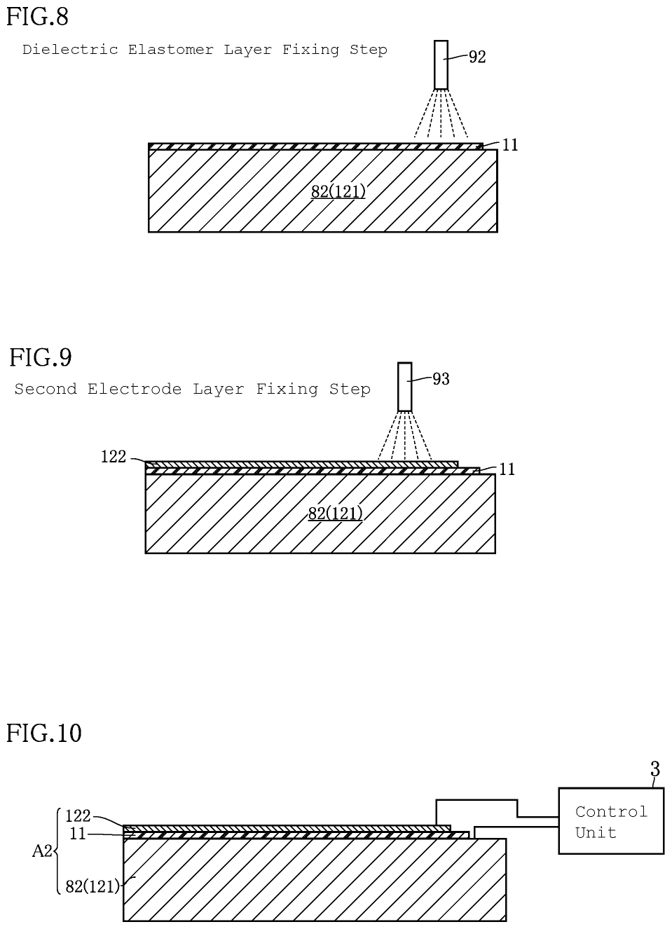

FIGS. 8 and 9 illustrate a method for manufacturing a dielectric elastomer transducer according to a second embodiment of the present invention.

First, a dielectric elastomer layer fixing step is performed as shown in FIG. 8. In this step, a target object 82 is prepared. The target object 82 is similar to the one described in the earlier embodiment, except that the target object 82 of this embodiment has a conductive surface. The surface of the target object 82 serves as the first electrode layer 121.

Next, a dielectric elastomer layer 11 is fixed to the surface of the target object 82. In the illustrated example, the dielectric elastomer layer 11 is formed by applying a material. This step is similar to the step described with reference to FIG. 2. That is, an elastomer material is applied through an applicator nozzle 92 to form the dielectric elastomer layer 11 fixed to the target object 82. Alternatively, the dielectric elastomer layer fixing step may use bonding in a manner described with reference to FIG. 6.

Subsequently, a second electrode fixing step is performed as shown in FIG. 9. In this step, a second electrode layer 122 is fixed to the dielectric elastomer layer 11. In the illustrated example, the second electrode layer 122 is formed by applying a material. That is, similarly to the step described with reference to FIG. 3, a conductive material is applied through an applicator nozzle 93 to form the second electrode layer 122 fixed to the dielectric elastomer layer 11. Alternatively, the second electrode layer fixing step may use bonding in a manner described with reference to FIG. 7.

FIG. 10 illustrates a dielectric elastomer transducer according to the second embodiment of the present invention. The dielectric elastomer transducer A2 of this embodiment includes the target object 82, which is utilized as the first electrode layer 121, and also includes the dielectric elastomer layer 11 and the second electrode layer 122. The dielectric elastomer layer 11 and the second electrode layer 122 are formed by applying appropriate materials.

The control unit 3 of this embodiment has similar functions as the control unit 3 connected to the dielectric elastomer transducer A1. The control unit 3 of this embodiment is connected to the target object 82 serving as the first electrode layer 121 and also to the second electrode layer 122.

The present embodiment ensures that the dielectric elastomer layer 11 and the second electrode layer 122 closely conform to the target object 82. In addition, since the conductive surface of the target object 82 is used as the first electrode layer 121, there is no need to prepare a first electrode layer 121 separately from the target object 82. That is, the dielectric elastomer transducer A2 has a portion that directly follows the shape and deformation of the target object 82. This configuration is preferable to provide the dielectric elastomer transducer A2 that is highly conformable.

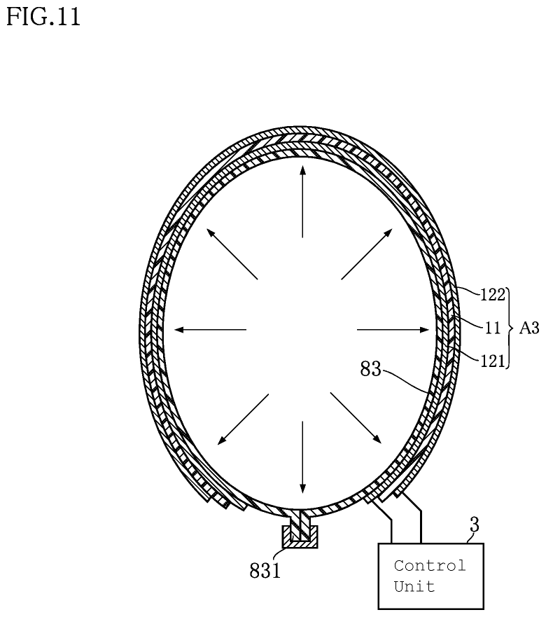

FIG. 11 illustrates a dielectric elastomer transducer according to a third embodiment of the present invention. In this embodiment, a target object 83 is a rubber balloon, and the dielectric elastomer transducer A3 includes the first electrode layer 121, the dielectric elastomer layer 11 and the second electrode layer 122 stacked on the target object 83. The first electrode layer 121, the dielectric elastomer layer 11 and the second electrode layer 122 are formed by applying appropriate materials.

The rubber balloon being the target object 83 is inflated to a spherical shape by the internal pressure, and thus the membrane of the rubber balloon is pulled in tension. In the manufacture of the dielectric elastomer transducer A3, the first electrode layer 121, the dielectric elastomer layer 11 and the second electrode layer 122 are sequentially formed by printing on the target object 83, which is a rubber balloon inflated to a predetermined pressure. Then, additional gas is injected into the target object 83 from a plug 831 to increase the internal pressure. As a result, the tension of the target object 83 is increased, and the dielectric elastomer layer 11 is pulled in tension. This is the initial state of the dielectric elastomer transducer A3 prior to operation. When the control unit 3 applies voltage between the first electrode layer 121 and the second electrode layer 122, the dielectric elastomer layer 11 is stretched. As a result, the size of the balloon-shaped target object 83 increases. That is, the size of the balloon-shaped target object 83 can be changed smaller or larger as desired, by controlling the voltage applied between the first electrode layer 121 and the second electrode layer 122.

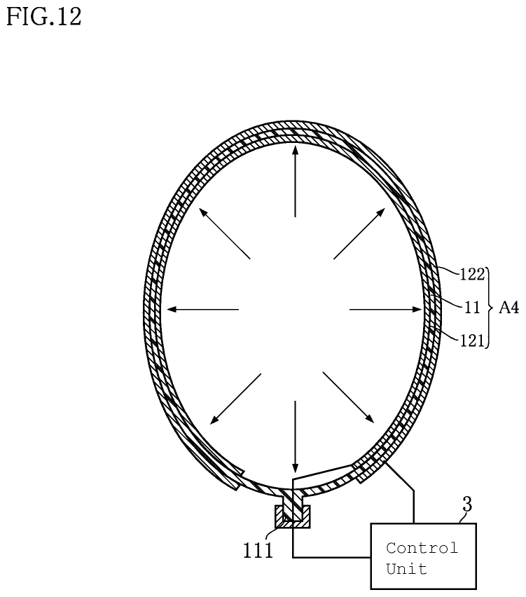

FIG. 12 illustrates a dielectric elastomer transducer according to a fourth embodiment of the present invention. The dielectric elastomer transducer A4 of the present embodiment includes the first electrode layer 121, the dielectric elastomer layer 11 and the second electrode layer 122. The dielectric elastomer layer 11 has a balloon shape similarly to the target object 83 of the second embodiment. The first electrode layer 121 is disposed on the inner surface of the dielectric elastomer layer 11. The first electrode layer 121 is formed by applying a conductive material to the inner surface of the dielectric elastomer layer 11. The conductive material may be applied by spraying, for example. The second electrode layer 122 is disposed on the outer surface of the dielectric elastomer layer 11. The second electrode layer 122 is formed by applying a conductive material to the outer surface of the dielectric elastomer layer 11. The conductive material may be applied by spraying.

The dielectric elastomer layer 11 is inflated to a spherical shape by increasing the internal pressure above atmospheric pressure and is hermetically closed with a plug 111, for example. The plug 111 is configured to allow a wire to extend therethrough to connect the control unit 3 to the first electrode layer 121. In the initial state, the internal pressure of the dielectric elastomer layer 11 is above atmospheric pressure. When the control unit 3 applies voltage between the first electrode layer 121 and the second electrode layer 122, the dielectric elastomer layer 11 is stretched. As a result, the size of the balloon-shaped dielectric elastomer transducer A4 increases. That is, the size of the balloon-shaped dielectric elastomer transducer A4 can be increased and decreased as desired, by controlling the voltage applied between the first electrode layer 121 and the second electrode layer 122. As such, the dielectric elastomer transducer A4 can be used as an actuator.

Neither the method for manufacturing a dielectric elastomer transducer nor the dielectric elastomer transducer according to the present invention is limited to the specific embodiments described above. Various design changes can be made to the specific details of the method for manufacturing a dielectric elastomer transducer and the dielectric elastomer transducer according to the present invention.

### [Clause 1]

A method for manufacturing a dielectric elastomer transducer, the method comprising:
a first electrode layer fixing step of fixing a first electrode layer to a target object;
a dielectric elastomer layer fixing step of fixing a dielectric elastomer layer to the first electrode layer; and
a second electrode layer fixing step of fixing a second electrode layer to the dielectric elastomer layer.

### [Clause 2]

The method according to Clause 1, wherein the first electrode layer fixing step includes material application to form the first electrode layer fixed to the target object.

### [Clause 3]

The method according to Clause 1, wherein the first electrode layer fixing step includes bonding to fix the first electrode layer to the target object.

### [Clause 4]

The method according to Clause 2 or 3, wherein at least one of the dielectric elastomer layer fixing step or the second electrode layer fixing step includes material application to form the corresponding layer.

### [Clause 5]

The method according to Clause 2 or 3, wherein at least one of the dielectric elastomer layer fixing step or the second electrode layer fixing step includes bonding to fix the corresponding layer.

### [Clause 6]

A method for manufacturing a dielectric elastomer transducer, the method comprising:
a dielectric elastomer layer fixing step of fixing a dielectric elastomer layer to a surface of a target object, the surface being composed of an electric conductor and comprising a first electrode layer; and
a second electrode layer fixing step of fixing a second electrode layer to the dielectric elastomer layer.

### [Clause 7]

A method for manufacturing a dielectric elastomer transducer, the method comprising:
a first electrode layer fixing step of fixing a first electrode layer to a surface of a dielectric elastomer layer that is inflatable to a spherical shape by increasing internal pressure, the surface being an inner surface of the dielectric elastomer layer; and
a second electrode layer fixing step of fixing a second electrode layer to an outer surface of the dielectric elastomer layer.

### [Clause 8]

A dielectric elastomer transducer comprising:

a first electrode layer formed by applying a material to a target object;

a dielectric elastomer layer fixed to the first electrode layer; and

a second electrode layer fixed to the dielectric elastomer layer.

### [Clause 9]

A dielectric elastomer transducer comprising:

a first electrode layer composed of an electrically conductive surface of a target object;

a dielectric elastomer layer fixed to the first electrode layer; and

a second electrode layer fixed to the dielectric elastomer layer.

### [Clause 10]

A dielectric elastomer transducer comprising:

a dielectric elastomer layer inflatable to a spherical shape by increasing internal pressure;

a first electrode layer fixed to an inner surface of the dielectric elastomer layer; and

a second electrode layer fixed to an outer surface of the dielectric elastomer layer.

1. A method for manufacturing a dielectric elastomer transducer, the method comprising:
a first electrode layer fixing step of fixing a first electrode layer to a target object;
a dielectric elastomer layer fixing step of fixing a dielectric elastomer layer to the first electrode layer; and
a second electrode layer fixing step of fixing a second electrode layer to the dielectric elastomer layer.

2. The method according to claim 1, wherein the first electrode layer fixing step includes material application to form the first electrode layer fixed to the target object.

3. The method according to claim 1, wherein the first electrode layer fixing step includes bonding to fix the first electrode layer to the target object.

4. The method according to claim 2, wherein at least one of the dielectric elastomer layer fixing step or the second electrode layer fixing step includes material application to form the corresponding layer.

5. The method according to claim 2, wherein at least one of the dielectric elastomer layer fixing step or the second electrode layer fixing step includes bonding to fix the corresponding layer.

6. A method for manufacturing a dielectric elastomer transducer, the method comprising:
a dielectric elastomer layer fixing step of fixing a dielectric elastomer layer to a surface of a target object, the surface being composed of an electric conductor and comprising a first electrode layer; and
a second electrode layer fixing step of fixing a second electrode layer to the dielectric elastomer layer.

7. A method for manufacturing a dielectric elastomer transducer, the method comprising:
a first electrode layer fixing step of fixing a first electrode layer to a surface of a dielectric elastomer layer that is inflatable to a spherical shape by increasing internal pressure, the surface being an inner surface of the dielectric elastomer layer; and
a second electrode layer fixing step of fixing a second electrode layer to an outer surface of the dielectric elastomer layer.

8. A dielectric elastomer transducer comprising:
a first electrode layer formed by applying a material to a target object;
a dielectric elastomer layer fixed to the first electrode layer; and
a second electrode layer fixed to the dielectric elastomer layer.

9. A dielectric elastomer transducer comprising:
a first electrode layer composed of an electrically conductive surface of a target object;
a dielectric elastomer layer fixed to the first electrode layer; and
a second electrode layer fixed to the dielectric elastomer layer.

10. A dielectric elastomer transducer comprising:
a dielectric elastomer layer inflatable to a spherical shape by increasing internal pressure;
a first electrode layer fixed to an inner surface of the dielectric elastomer layer; and
a second electrode layer fixed to an outer surface of the dielectric elastomer layer.

11. The method according to claim 3, wherein at least one of the dielectric elastomer layer fixing step or the second electrode layer fixing step includes material application to form the corresponding layer.

12. The method according to claim 3, wherein at least one of the dielectric elastomer layer fixing step or the second electrode layer fixing step includes bonding to fix the corresponding layer.
